(19) United States
(12) Patent Application Publication
(10) Pub. No.: US 2003/0015751 A1
(43) Pub. Date: Jan. 23, 2003

(54) Semiconductor memory device including memory cells and peripheral circuits and method for manufacturing the same

(76) Inventor: Kazuaki Isobe, Yokohama-shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 10/197,586

(22) Filed: Jul. 18, 2002

(30) Foreign Application Priority Data
Jul. 19, 2001 (JP) 2001-220189

(51) Int. Cl. H01L 21/336; H01L 29/792

(52) U.S. Cl. 257/314; 438/257; 438/258; 438/266; 438/275; 257/326

(57) ABSTRACT

A semiconductor memory device includes a first well of a second conductivity type formed in a surface portion of a semiconductor substrate of a first conductivity type and a second well of the first conductivity type formed in a surface portion of the first well. An element isolating insulation film to isolate a memory cell region from a peripheral region is formed in a surface portion of the second well. A cell transistor is provided in a region of the second well in the memory cell region. A first contact layer of the second conductivity type to provide the first well with a potential is formed in a surface portion of the first well in the peripheral region. A second contact layer of the first conductivity type to provide the second well with a potential is formed in a surface portion of the second well in the peripheral region.

### CROSS-REFERENCE TO RELATED APPLICATIONS

This application is based upon and claims the benefit of priority from the prior Japanese Patent Application No. 2001-220189, filed Jul. 19, 2001, the entire contents of which are incorporated herein by reference.

### BACKGROUND OF THE INVENTION

1. Field of the Invention

The present invention relates to a semiconductor memory device including both memory cells and peripheral circuits, and a method for manufacturing the same.

2. Description of the Related Art

Generally, in a semiconductor memory device such as a flash memory, a chip contains not only memory cells but also peripheral circuits (e.g., logic circuits) necessary for operations of the device. Accordingly, elements constituting the peripheral circuits, such as resistors and transistors, are also formed on the chip.

When a flash memory of the above structure is manufactured, the manufacturing process is required to be efficient in order to reduce the manufacturing cost. For this purpose, cell transistors constituting memory cells and transistors constituting peripheral circuits are manufactured substantially in the same process. The efficiency of the manufacturing can be improved in this manner.

FIG. 21A is a top plan view of a conventional flash EEPROM (Electrically Erasable Programmable Read Only Memory). As shown in FIG. 21A, the flash memory has a cell region and a peripheral region. Memory cells (not shown) are formed in the cell region. Peripheral circuits, for example, MOSFETs (Metal Oxide Semiconductor Field Effect Transistors) (not shown), are formed in the peripheral region. An N-well 32a is formed in a semiconductor substrate 31 and a P-well 33 is formed in the N-well 32a. A silicon oxide film 34a is formed to surround the N-well 32a. The silicon oxide film 34a isolates the cell region and the peripheral region.

FIG. 21B is a cross-sectional view of the flash memory shown in FIG. 21A, taken along the line XXIB-XXIB. A silicon oxide film 34 isolates element regions, and the silicon oxide film 34a isolates the cell region and the peripheral region. As will be described later, the cell region and the peripheral region, separated by the silicon oxide film 34a, are manufactured in different steps. A cell transistor 37 is formed on the surface of the semiconductor substrate 31 in the cell region. An N-type MOSFET 44 is formed on the surface of the semiconductor substrate 31 in the peripheral region.

FIGS. 22 to 29 show steps for manufacturing the flash memory of the above structure. As shown in FIG. 22, N-wells 32a and 32b are formed in a surface region of the semiconductor substrate 31, and a P-well 33 is formed in a surface region of the N-well 32a. Silicon oxide films 34 and 34a are formed in the surface region of the semiconductor substrate 31. Then, a gate insulating film material 40a, a first gate electrode material 41a and a gate electrode insulating film material 42a are formed on the overall surface of the semiconductor device. Thereafter, the gate electrode insulating film material 42a, the first gate electrode material 41a and the gate insulating film material 40a in the peripheral region are removed. At the same time, an upper portion of the silicon oxide film 34a is removed. Then, a gate insulating film material 46a is formed in the peripheral region, and thereafter a second gate electrode material 43a is formed on the overall surface of the semiconductor device.

Next, as shown in FIG. 23, a photoresist 54 is formed by the photolithography. The photoresist 54 has a gate pattern of the cell region and covers the peripheral region and an about one fourth of the silicon oxide film 34a on the peripheral region side.

Then, as shown in FIG. 24, the second gate electrode material 43a, the gate electrode insulating film material 42a and the first gate electrode material 41a are etched by the photolithography using the photoresist 54 as a mask. As a result, a gate electrode 39 is formed.

Thereafter, as shown in FIG. 25, a photoresist 55 is formed by the photolithography. The photoresist 55 has a gate pattern of a MOSFET 44 and covers the cell region.

Thereafter, as shown in FIG. 26, the second gate electrode material 43a is etched, using the photoresist 55 as a mask. As a result, a gate electrode 47 is formed.

Subsequently, as shown in FIG. 27, the photoresist 55 is removed. Then, a photoresist 56 is formed by the photolithography. Thereafter, source and drain regions 38a and 38b are formed, using the photoresist 56 as a mask.

Subsequently, as shown in FIG. 28, the photoresist 56 is removed. Then, a photoresist 57 is formed by the photolithography. Thereafter, an N-type impurity diffusion layer 35 is formed, using the photoresist 57 as a mask.

Thereafter, as shown in FIG. 29, the photoresist 57 is removed. Then, a photoresist 58 is formed by the photolithography. Thereafter, using the photoresist 58 as a mask, a P-type impurity diffusion layer 36 is formed in a surface region of the P-well 33 and source and drain regions 45a and 45b are formed in a surface region of the N-well 32b.

Subsequently, the photoresist 58 is removed as shown in FIG. 21B. Thereafter, the overall surface of the semiconductor device is covered with a BPSG (Boro-Phospho Silicate Glass) or PSG (Phospho Silicate Glass) film. Then, a contact hole is formed in the BPSG or PSG film. Thereafter, a wiring pattern, a contact and the like are formed.

In the flash memory having the above structure, the silicon oxide film 34a isolating the cell region and the peripheral region surrounds the N-well 32a, as shown in FIGS. 21A and 21B. If the flash memory is manufactured through the above manufacturing steps, the following problems will arise: after the step shown in FIG. 22, several photolithography steps are required until the gate electrodes 39 and 47 and the source and drain regions 38a and 38b of the cell transistor 37 are formed, as shown in FIG. 27. In order to improve the efficiency of the manufacturing process, it is important to reduce the number of steps for producing a semiconductor memory device. Therefore, the number of steps need be reduced to a minimum.

### BRIEF SUMMARY OF THE INVENTION

According to a first aspect of the present invention, there is provided a semiconductor memory device having a memory cell region in which a cell transistor is formed and a peripheral region in which a peripheral circuit is formed, the device comprising: a semiconductor substrate of a first conductivity type; a first well of a second conductivity type selectively formed in a surface portion of the semiconductor substrate; a second well of the first conductivity type selectively formed in a surface portion of the first well; a first element isolating insulation film formed in a surface portion of the second well, the first element isolating insulation film isolating the memory cell region from the peripheral region; a cell transistor provided in the second well in the memory cell region, the cell transistor comprising a gate electrode provided on the second well with a gate insulating film interposed therebetween and source and drain layers formed in the second well to sandwich a portion of the second well under the gate electrode; a first contact layer of the second conductivity type formed in a surface portion of the first well in the peripheral region, the first contact layer providing the first well with a potential; and a second contact layer of the first conductivity type formed in a surface portion of the second well in the peripheral region, the second contact layer providing the second well with a potential.

According to a second aspect of the present invention there is provided a method for manufacturing a semiconductor memory device having a memory cell region in which a cell transistor is formed and a peripheral region in which a peripheral circuit is formed, the method comprising: forming a well in a surface portion of a semiconductor substrate; forming an element isolating insulation film in a plane of the well so as to surround the memory cell region, the element isolating insulation film isolating the memory cell region from the peripheral region; forming a first gate insulation film, a first conductive film and a first insulation film, successively, on the well in the memory cell region; forming a second gate insulation film outside the well in the peripheral region; forming a second conductive film over the first insulation film and the second gate insulation film; forming a mask layer on the second conductive film, the mask layer having a gate pattern of the cell transistor and covering the peripheral region; forming a gate structure of the cell transistor by etching the second conductive film, the first insulation film and the first conductive film in the memory cell region, using the mask layer as a mask; forming source and drain regions of the cell transistor by implanting an impurity into the surface portion of the semiconductor substrate, using the mask layer as a mask; and forming a gate structure and source and drain regions of the peripheral transistor.

### BRIEF DESCRIPTION OF THE SEVERAL VIEWS OF THE DRAWING

FIG. 1A is a plan view of a flash memory according to an embodiment of the present invention, and FIG. 1B is a cross-sectional view of the flash memory shown in FIG. 1A; FIGS. 2, 3, 4, 5, 6, 7, 8, 9, 10, 11, 12, 13, 14, 15, 16, 17, 18, and 19 are cross-sectional views showing steps for manufacturing the flash memory shown in FIGS. 1A and 1B;

FIG. 20A is a plan view of a flash memory according to an embodiment of the present invention, and FIG. 20B is a plan view of a conventional flash memory;

FIG. 21A is a plan view of a conventional flash memory, and FIG. 21B is a cross-sectional view of the flash memory shown in FIG. 21A; and

FIGS. 22, 23, 24, 25, 26, 27, 28, and 29 are cross-sectional views showing steps for manufacturing the flash memory shown in FIGS. 21A and 21B.

### DETAILED DESCRIPTION OF THE INVENTION

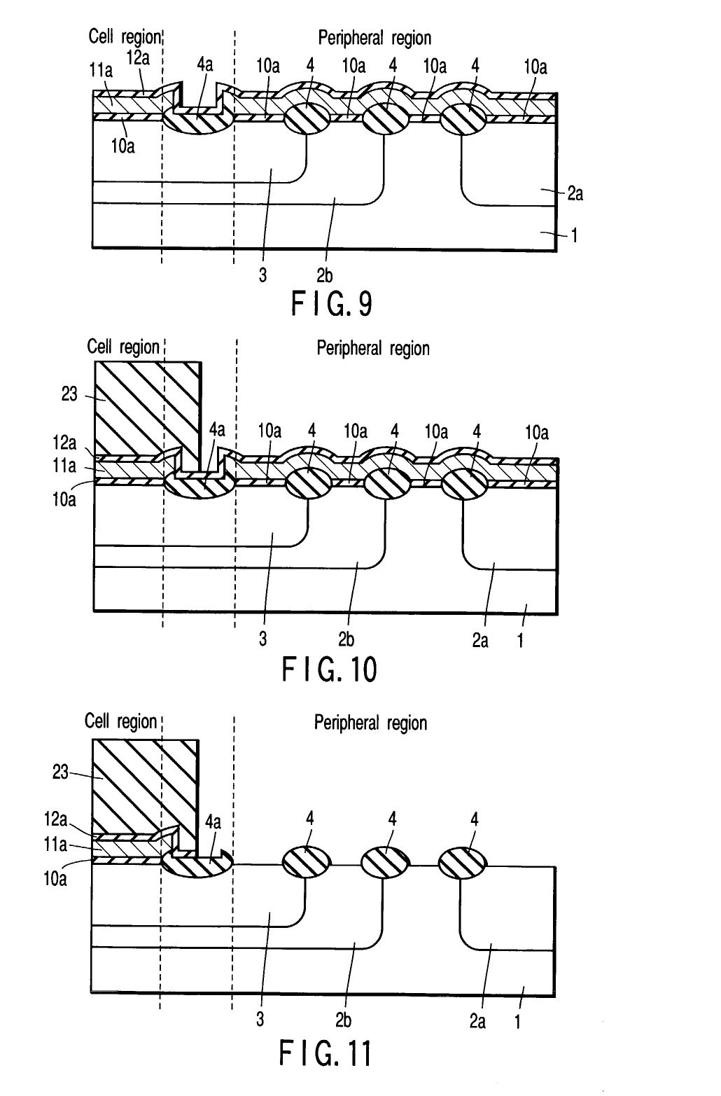

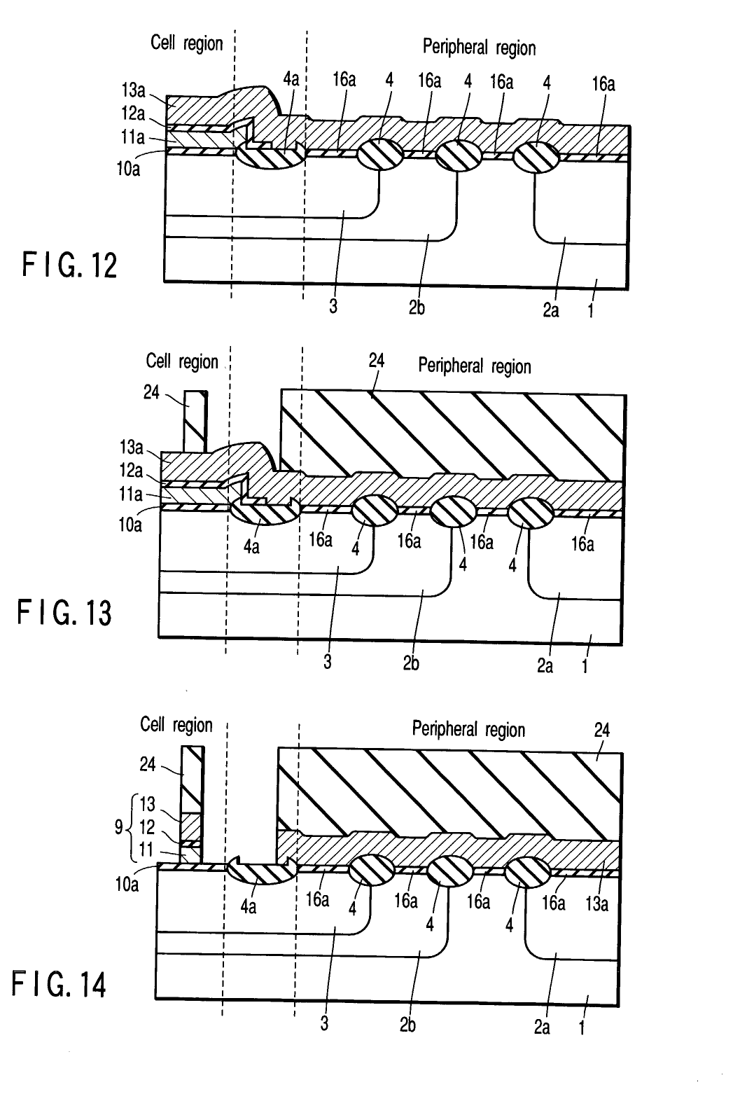

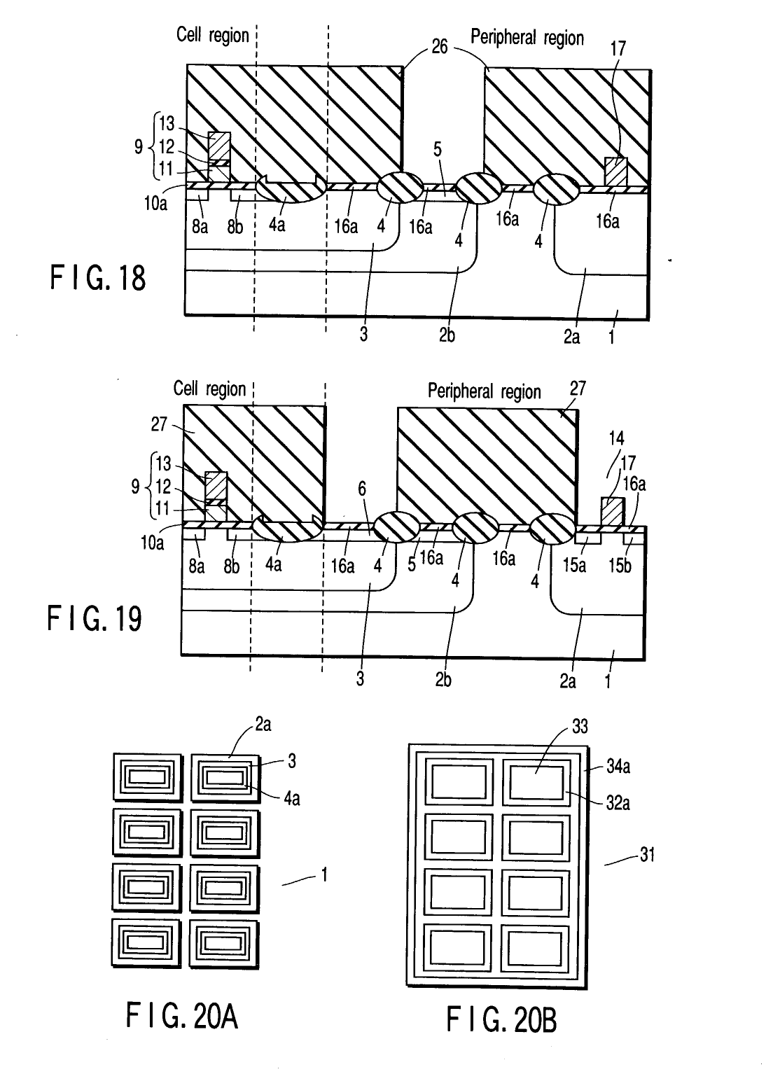

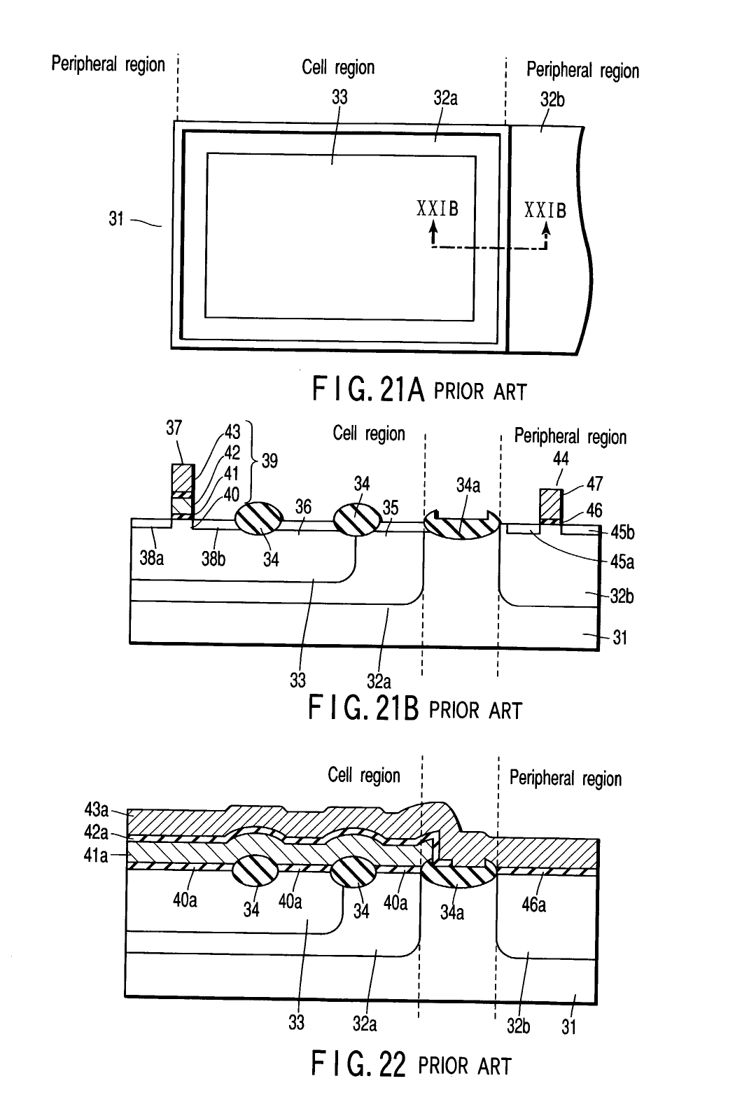

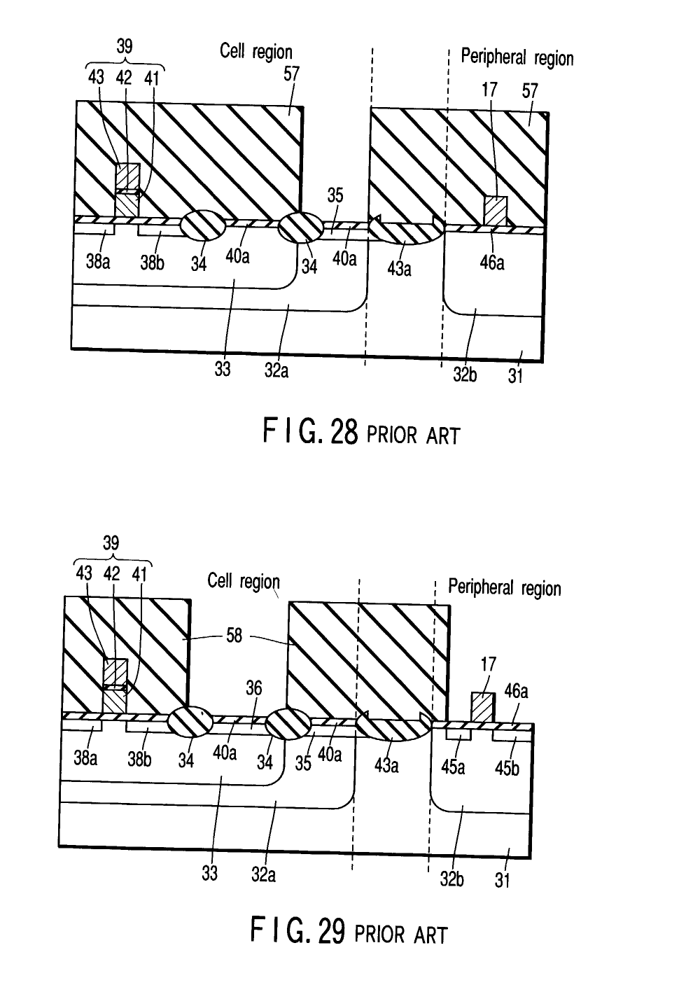

In the process of developing the present invention, the inventors researched a flash memory that can be manufactured through steps less than those described above with reference to FIGS. 22 to 29, and a method for manufacturing the same. As a result, the inventors founded the following findings.

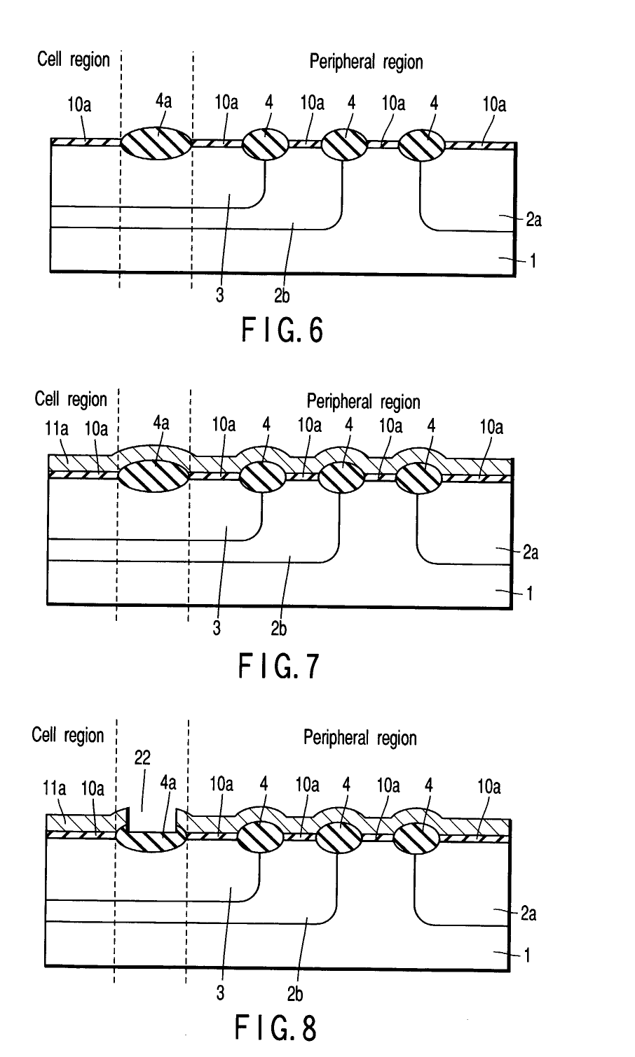

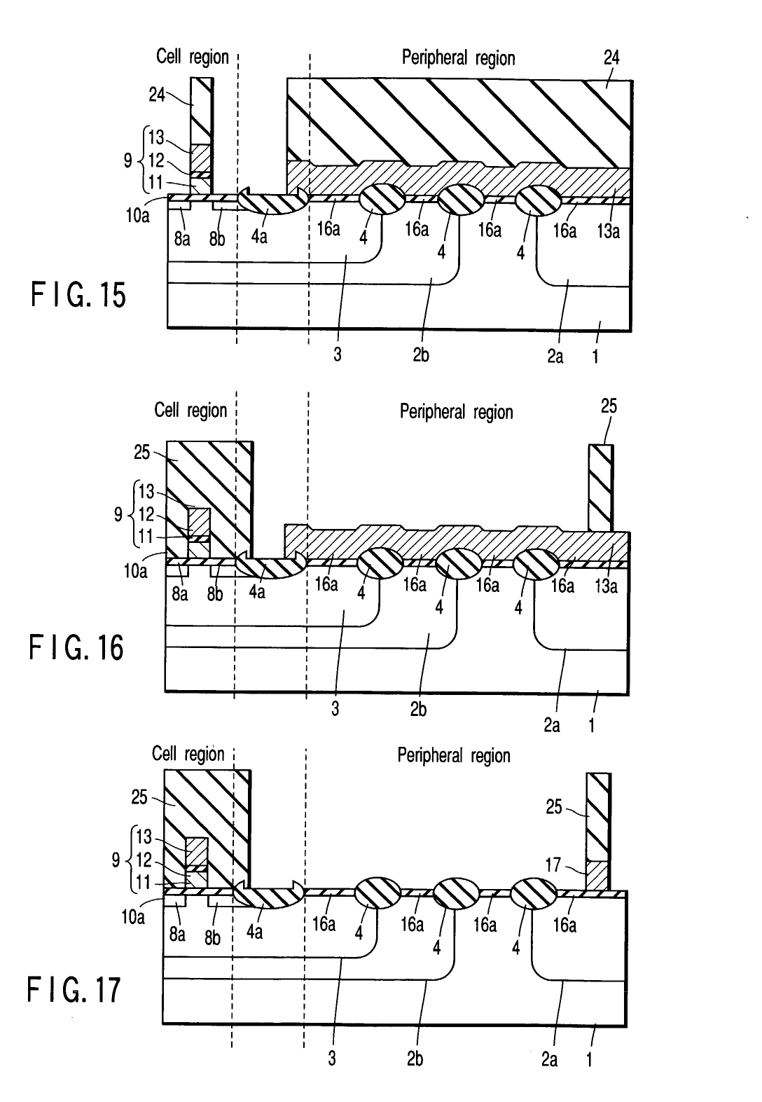

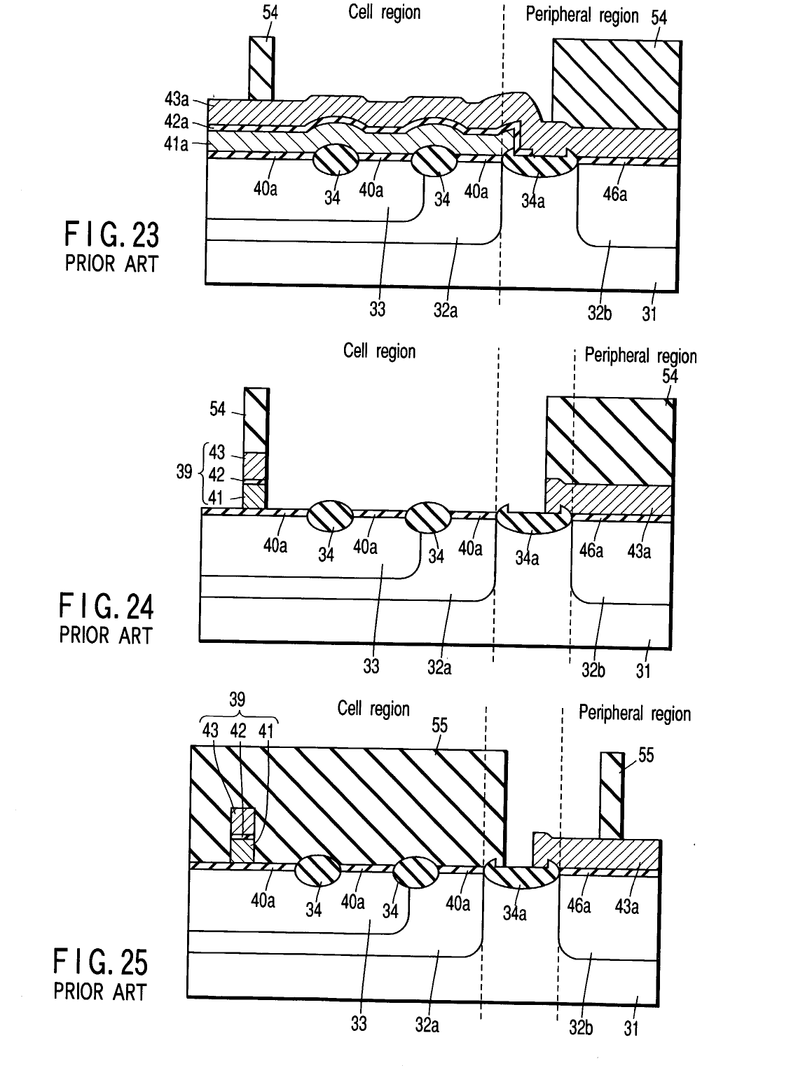

First, the number of steps can be reduced in the following manner. In the step shown in FIG. 24, a gate pattern for the gate electrode 39 is formed by the photolithography. Then, an N-type impurity is ion-implanted into the surface region of the semiconductor substrate 31 using the photoresist as a mask, and thereafter the photoresist 54 is removed in the next step. This ion implantation step forms the source and drain regions 38a and 38b and the N-type impurity diffusion layer 35 as shown in FIG. 21B. With this method, the step shown in FIG. 27, i.e., the process of forming the photoresist 56 and transferring a pattern to the photoresist by the photolithography, can be omitted.

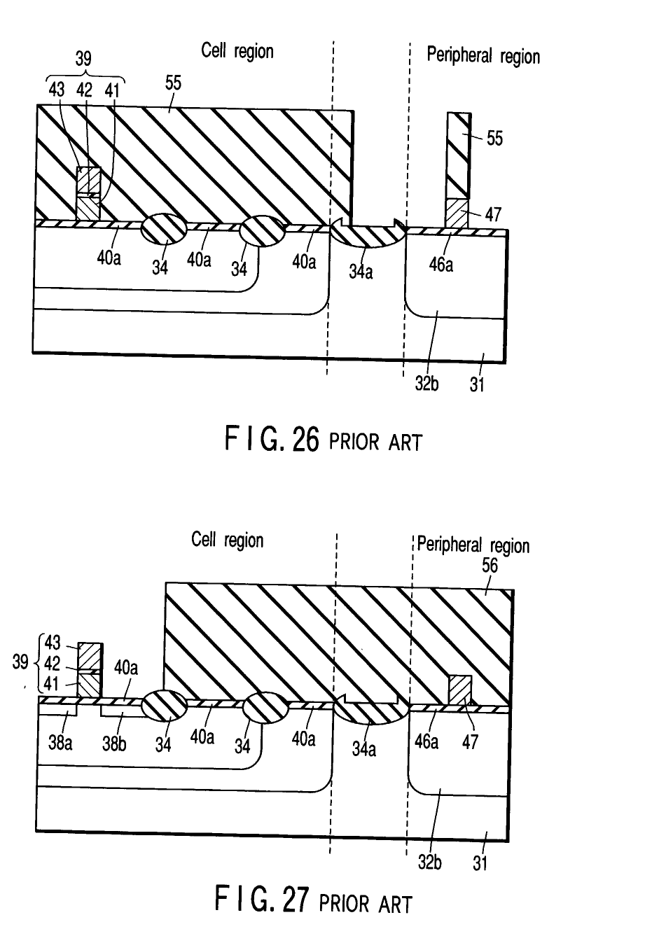

However, according to this method, when the N-type impurity is implanted into the semiconductor substrate 31, it is also implanted into a region where the P-type impurity diffusion layer 36 shown in FIG. 21B is to be formed. Therefore, when the P-type impurity is implanted into this region in the step shown in FIG. 28, the P-type impurity concentration cannot be sufficiently high. Therefore, in a later process, a contact cannot be formed in the P-type impurity diffusion layer 36. This problem is particularly serious in a case where the impurity concentration of the P-type impurity diffusion layer 36 is not more than eight times that of the source and drain regions 38a and 38b.

An embodiment of the present invention attained on the basis of the above finding will be described with reference to the drawings. In the following description, structural elements having substantially the same function and structure are identified by the same reference numeral, and the explanation thereof will not be repeated unless it is particularly necessary.

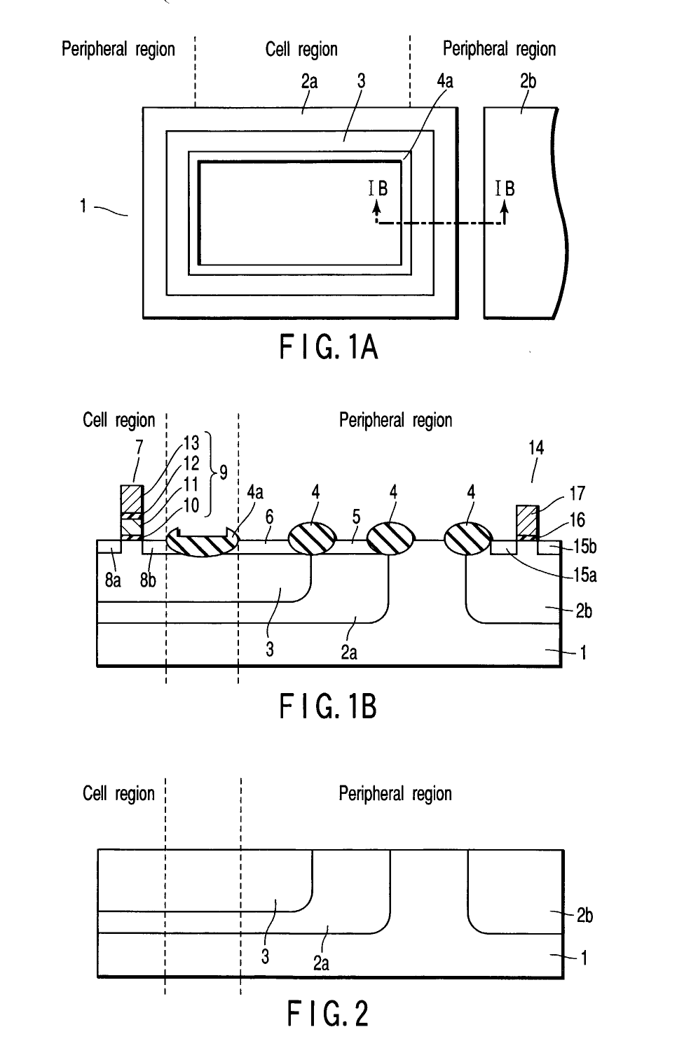

FIG. 1A is a top plan view of a flash EEPROM according to an embodiment of the present invention. As shown in FIG. 1A, the flash memory has a cell region (memory cell region) and a peripheral region. Cell transistors (not shown) of memory cells are formed in the cell region. Peripheral transistors constituting peripheral circuits, for example, MOSFETs (not shown) are formed in the peripheral region. A substantially rectangular N-well 2 is formed in a semiconductor substrate 1 and a substantially rectangular P-well 3 is formed in the N-well 2. A substantially rectangular silicon oxide film 4a is formed in the plane of the P-well 3. The region surrounded by the silicon oxide film 4a is defined as a cell region, which is isolated from the peripheral region.

FIG. 1B is a cross-sectional view of the flash memory shown in FIG. 1A, taken along the line 1B-1B. As shown in FIG. 1B, N-wells 2a and 2b are formed at regular intervals in a surface region of the substrate 1, which is made of a P-type semiconductor, for example, silicon. A P-well 3 is formed in a surface region of the N-well 2a. Silicon oxide films 4 are formed at the edge portions of the N-wells 2a and 2b and the boundary between the N-well 2a and the P-well 3. The silicon oxide films 4 function as element isolating insulation films, which isolate element regions.

A silicon oxide film 4a is formed in the P-well 3 in the surface region of the semiconductor substrate 1. The silicon oxide film 4a is formed between the cell region and the peripheral region, and functions as an insulating film isolating these regions. The silicon oxide film 4a has a substantially U-shaped trench in an upper portion thereof. The silicon oxide film 4a is wider than the other silicon oxide films 4, and has predetermined dimensions. This is because the patterns for lithography steps are different in the cell region and the peripheral region isolated by the silicon oxide film 4a, and therefore, it is necessary to have a margin while considering the processing accuracy of photoresist, the positioning accuracy, etc. The reason why the patterns for steps for lithography are different in the cell region and the peripheral region is that the gate structures are different in the cell region and the peripheral region, as will be described later.

An N-type impurity diffusion layer (N-well contact layer) 5 is formed in the N-well 2a in the peripheral region. A P-type impurity diffusion layer (P-well contact layer) 6 is formed between the silicon oxide film 4a and the silicon oxide film 4 at the boundary between the N-well 2a and the P-well 3. The P-type impurity diffusion layer 6 has an impurity concentration of, for example, 2×10²⁰ cm⁻³. A cell transistor 7 of the memory cell is formed on the semiconductor substrate 1 in a portion adjacent to the silicon oxide film 4a. The cell transistor 7 comprises source and drain regions 8a and 8b and a gate electrode 9. The source and drain regions 8a and 8b are formed in the surface region of the semiconductor substrate 1 at a predetermined distance therebetween. They have an impurity concentration of, for example, 5×10¹⁹ cm⁻³. The gate electrode 9 comprises a floating gate electrode 11, a gate electrode insulating film 12 and a control gate electrode 13. The gate electrode 9 is formed on a gate insulating film 10 formed between the source and drain regions 8a and 8b on the semiconductor substrate 1.

For example, an P-type MOSFET 14 is formed on the semiconductor substrate 1 in the N-well 2b. The MOSFET 14 constitutes a peripheral circuit. The MOSFET 14 comprises source and drain regions 15a and 15b and a gate electrode 17. The source and drain regions 15a and 15b are formed in the surface region of the semiconductor substrate 1 at a predetermined distance therebetween. The gate electrode 17 is formed on a gate insulating film 16 formed between the source and drain regions 15a and 15b on the semiconductor substrate 1.

FIGS. 2 to 19 sequentially show steps for manufacturing the flash memory having the structure described above. A method for manufacturing the flash memory will now be described with reference to FIGS. 2 to 19.

First, phosphorus is implanted into the surface region of the semiconductor substrate 1. Then, for example, phosphorus is diffused (driven in) by high-temperature annealing. As a result, as shown in FIG. 2, the N-well 2a and 2b are selectively formed at a predetermined distance therebetween. Then, for example, boron is implanted into the N-well 2a and thereafter diffused by means of high-temperature annealing. As a result, a P-well 3 is selectively formed in a surface region of the N-well 2a.

Then, as shown in FIG. 3, a silicon oxide film 20 is formed on the overall surface of the semiconductor substrate 1 by, for example, thermal oxidation. A silicon nitride film 21 is formed on the silicon oxide film 20 by, for example, CVD (Chemical Vapor Deposition).

Subsequently, photoresist (not shown) is formed on the silicon nitride film 21. A pattern having openings for a portion of the P-well 3, an edge portion of the P-well 3 and edge portions of the N-wells 2a and 2b is transferred to the photoresist by the photolithography. Using the photoresist as a mask, the portions of the silicon nitride film 21 and the silicon oxide film 20 are removed. This removal is performed by anisotropic etching, such as RIE (Reactive Ion Etching). As a result, as shown in FIG. 4, portions of the semiconductor substrate 1 corresponding to the openings are exposed. Then, the photoresist is removed.

Subsequently, the semiconductor device is oxidized in an atmosphere containing moisture at a temperature of, for example, about 1000° C. As a result, as shown in FIG. 5, silicon oxide films 4 and 4a are formed on the exposed portions of the semiconductor substrate 1. The thickness of the silicon oxide films 4 and 4a is about 1 μm, for example.

Then, the silicon nitride film 21 is removed by wet-etching using a phosphoric acid solution heated at a temperature of, for example, 180° C. Thereafter, the silicon oxide film 20 is removed by wet-etching using, for example, NH₄F. As a result, that portion of the surface of the semiconductor substrate 1 which is not covered by the silicon oxide films 4 and 4a is exposed. Then, a silicon oxide film (not shown) is formed on the overall surface of the semiconductor apparatus. Then, an impurity is introduced into regions where the cell transistor 7 and the MOSFET 14 are to be formed. The introduction of the impurity is performed under such conditions that the threshold voltages of the cell transistor 7 and the MOSFET 14 are set to desired values. Then, the silicon oxide film is removed. Then, as shown in FIG. 6, a gate insulating film material 10a is formed on the exposed portion of the semiconductor substrate 1 by, for example, thermal oxidation. In a later process, a gate insulating film 10 of the cell transistor 7 of the memory cell is formed of the gate insulating film material 10a.

Subsequently, as shown in FIG. 7, a first gate electrode material 11a, made of polysilicon doped with an impurity, for example, phosphorus, is formed on the overall surface of the semiconductor device by means of, for example, the CVD. The floating gate electrode 11 of the memory cell transistor is formed of the first gate electrode material 11a in a later step.

Subsequently, photoresist (not shown) is deposited on the overall surface of the semiconductor device. Then, a pattern having a trench at a position corresponding to a substantially central portion of the silicon oxide film 4a is transferred to the photoresist using the photolithography. Thereafter, the first gate electrode material 11a and the silicon oxide film 4a are subjected to anisotropic etching, using the photoresist as a mask. The etching is carried out by, for example, RIE. As a result, as shown in FIG. 8, a portion of the first gate electrode 11a corresponding to the pattern trench is removed, and an upper portion of the silicon oxide film 4a is etched to form a substantially U-shaped slit 22. Then, the photoresist is removed.

Subsequently, as shown in FIG. 9, a gate electrode insulating film material 12a is deposited on the overall surface of the semiconductor device by means of, for example, the CVD. The gate electrode insulating film material 12a has a laminated structure made of, for example, silicon oxide films and a silicon nitride film sandwiched therebetween. The gate electrode insulating film 12 of the cell transistor 7 in the memory cell is formed of the gate electrode insulating film material 12a in a later step.

Subsequently, photoresist 23 is deposited on the overall surface of the semiconductor device. Then, a pattern, for leaving that portion of the photoresist 23 which covers the cell region and substantially half the slit 2 on the cell region side as shown in FIG. 10, is transferred to the photoresist 23 by means of the photolithography.

Thereafter, a portion of the gate electrode insulating film material 12a is removed, using the photoresist 23 as a mask. This removal is performed by anisotropic etching, such as the RIE. Then, a portion of the first gate electrode material 11a is removed by the CDE (Chemical Dry Etching), using the photoresist 23 as a mask. Thereafter, a portion of the gate insulating film 10a is removed by the wet-etching, using, for example, NH₄F. Thus, the structure as shown in FIG. 11 is obtained.

Subsequently, the photoresist 23 is removed. Then, a gate insulating film material 16a is formed on the semiconductor substrate 1 in the peripheral region. The gate insulating film 16 of the MOSFET 14 is formed of this gate insulating film material 16a in a later step. Then, as shown in FIG. 12, a second gate electrode material 13a is deposited on the overall surface of the semiconductor device by, for example, the CVD. The control gate electrode 13 of the cell transistor 7 and the gate electrode 17 of the MOSFET 14 are formed of the second gate electrode material 13a in a later step.

Subsequently, photoresist 24 is deposited on the overall surface of the semiconductor device. A pattern is transferred to the photoresist 24 by the photolithography. As shown in FIG. 13, the pattern has a shape to form a gate electrode at a position a predetermined distance away from the silicon oxide film 4a in the cell region, and leave the photoresist on the peripheral region and about one fourth of the silicon oxide film 4a on the peripheral region side.

Thereafter, as shown in FIG. 14, the second gate electrode material 13a, the gate electrode insulating film material 12a and the first gate electrode material 11a are etched, using the photoresist 24 as a mask. As a result, the gate electrode 9 of the cell transistor 7 is formed.

Subsequently, ions are implanted into the surface region of the semiconductor substrate 1, using the photoresist 24 and the gate electrode 9 as a mask. As a result, as shown in FIG. 15, the ions are diffused in a self-aligning manner, so that the source drain regions 8a and 8b are formed in proximity to the gate electrode 9.

Subsequently, the photoresist 24 is removed. Then, photoresist 25 is deposited on the overall surface of the semiconductor device. Thereafter, a pattern is transferred to the photoresist 25 by the photolithography. As shown in FIG. 16, the pattern has a shape corresponding to a gate pattern of the MOSFET 14 in the cell region, and to leave the photoresist on the cell region and about one fourth of the silicon oxide film 4a on the memory cell side.

Subsequently, as shown in FIG. 17, the second gate electrode material 13a is etched, using the photoresist 25 as a mask by means of anisotropic etching, such as the RIE. As a result of the etching, the gate electrode 17 of the MOSFET 14 is formed.

Subsequently, the photoresist 25 is removed. Then, photoresist 26 is deposited on the overall surface of the semiconductor device. Thereafter, a pattern having an opening corresponding to the N-well 2b, as shown in FIG. 18, is transferred to the photoresist 26 by the photolithography. Using the photoresist 26 as a mask, ions are implanted into the N-well 2b, so that an N-type impurity diffusion layer 5 is formed. At the same time, source and drain regions of an N-type MOSFET (not shown) are formed by the ion implantation.

Subsequently, the photoresist 26 is removed. Then, photoresist 27 is deposited on the overall surface of the semiconductor device. Thereafter, a pattern is transferred to the photoresist 27 by the photolithography. As shown in FIG. 19, the pattern has a shape so as to have an opening corresponding a region between the silicon oxide film 4a and the adjacent silicon oxide film 4 and a region where the MOSFET 14 is to be formed. Using the photoresist 27 as a mask, ions are implanted into the P-well 3. As a result, a P-type impurity diffusion layer 6 is formed in a surface region of the P-well 3, and at the same time, source and drain regions 15a and 15b of the P-type MOSFET 14 are formed.

Subsequently, the photoresist 27 is removed, as shown in FIG. 1B. Then, a BPSG or PSG film (not shown) is formed on the overall surface of the semiconductor device. Subsequently, photoresist (not shown) is deposited on the BPSG or PSG film. Then, a contact hole pattern for forming electrode wires is transferred to the photoresist by a photolithography process. Using the photoresist as a mask, the PSG or the BPSG is etched by, for example, the RIE. As a result, contact holes are formed. At this time, the gate insulating film material 10a on the source and drain regions 8a and 8b and the gate insulating film material 16a on the N-type impurity diffusion layer 5, the P-type impurity diffusion layer 6 and the source and drain regions 15a and 15b are removed. Then, the photoresist is removed.

Subsequently, an Al wiring film (not shown) is deposited on the overall surface of the semiconductor device by, for example, sputtering. At this time, the contact holes are filled with the Al wiring film. Then, photoresist (not shown) is deposited on the Al wiring film. A wring pattern is transferred to the photoresist by a photoresist process. Then, the Al wiring film is etched by, for example, the RIE, using the photoresist as a mask. As a result, a wiring pattern is formed. Thereafter, the photoresist is removed.

Subsequently, a PSG film (not shown) is deposited on the overall surface of the semiconductor device. Then, a silicon nitride film (not shown) is deposited on the PSG film by the PE-CVD. Thereafter, photoresist (not shown) is deposited on the silicon nitride film. Then, a pattern having an opening for a bonding pad is transferred to the photoresist by a photolithography process. Using the photoresist as a mask, the PSG film and the silicon nitride film are etched by, for example, the RIE. Then, the photoresist is removed, and a semiconductor device in the form of a wafer is completed.

According to the above embodiment, the silicon oxide film 4a for isolating the cell region and the peripheral region is formed inside the P-well 3 region. Therefore, the source and drain regions 8a and 8b can be formed by implanting ions into the P-well 3 using the photoresist 24 shown in FIG. 14 for forming the gate electrode 9 as a mask. Consequently, it is possible to omit the photolithography step for forming the source and drain regions 8a and 8b of the cell transistor, which was required according to the conventional method after the gate electrode 9 is formed.

The photoresist 24 shown in FIG. 14 covers the peripheral region and a part of the silicon nitride film 4a. In other words, the region where the P-type impurity diffusion layer 6 is to be formed is covered by the photoresist 24. Therefore, when the source and drain regions 8a and 8b are formed, using the photoresist 24 as a mask, no N-type impurity is implanted into the region where the P-type impurity diffusion layer 6 is to be formed. Consequently, the aforementioned photolithography step can be omitted and the P-type impurity diffusion layer 6 having a desired impurity concentration can be obtained.

Further, the above effect is particularly remarkable, when the embodiment of the present invention is applied to a semiconductor memory device in which the impurity concentration of the P-type impurity diffusion layer 6 is not more than eight times that of the source and drain regions 8a and 8b.

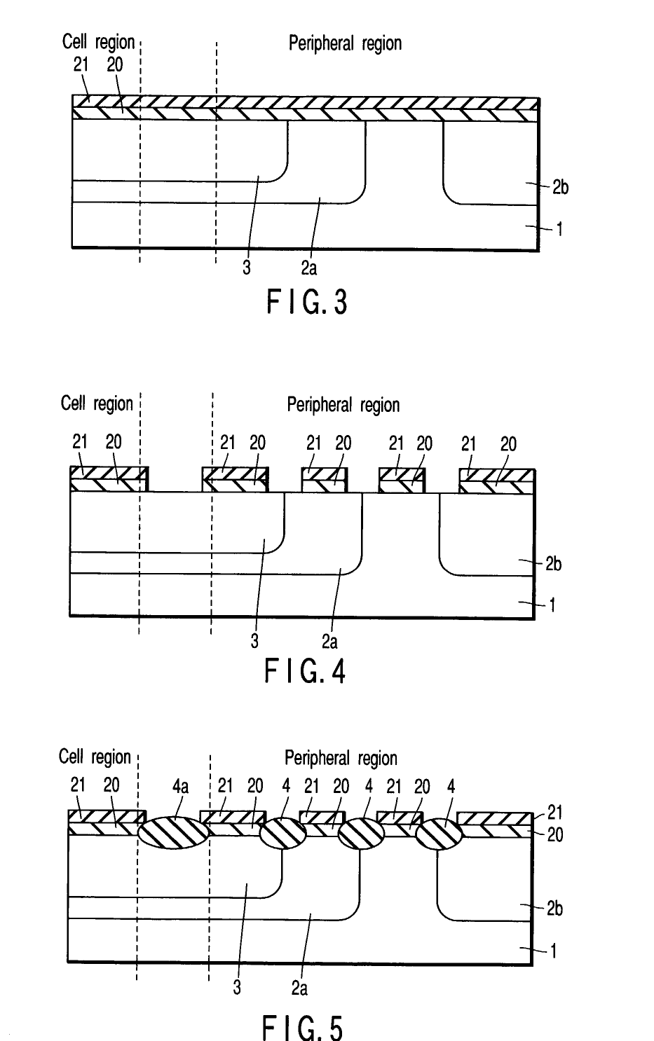

FIG. 20A is a plan view of a semiconductor memory device according to the above embodiment, in which N-wells 2a, P-wells 3 and silicon oxide films 4a are formed in the semiconductor substrate 1. FIG. 20B is a plan view of a conventional semiconductor memory device, in which N-wells 32a, P-wells 33 and silicon oxide films 34b are formed in the semiconductor substrate 31.

As shown in FIG. 20A, according to this embodiment, in principle, the sum of the areas of the silicon oxide films 4a, which require predetermined dimensions, is greater than the area of the silicon oxide film 34a of the conventional device shown in FIG. 20B. However, when this embodiment is applied to a combined element in which a cell region and a peripheral region are formed on a single substrate, the above effect is particularly remarkable for the following reason. Generally, in a combined element, the cell region is smaller than the peripheral region in size. Therefore, the aforementioned disadvantage caused by the increased area of the silicon oxide films 4a in a combined element can be ignored even if compared with the memory element having a cell region alone.

In this embodiment, the second gate electrode material 13a is made of a polysilicon film. However, it may be made of, for example, tungsten silicide or molybdenum silicide. Alternatively, it may be formed by SALICIDE (Self-Aligned Silicide process) technique.

Further, according to this embodiment, the element isolating insulation films 4 and 4a are formed by LOCOS (Local Oxidation of Silicon) technique. However, it may be formed by, for example, STI (Shallow Trench Isolation) technique.

Furthermore, when the source and drain regions 8a and 8b of the cell transistor 7 are formed in the step shown in FIG. 15, P-type impurity ions may be implanted, which is called pocket ion implantation. With this process, punch-through of the cell transistor 7 is prevented, so that the programming characteristic of the memory cell can be improved.

In the above embodiment, the N-type MOSFET is used as the cell transistor 7. However, a P-type MOSFET may be used instead.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device having a memory cell region in which a cell transistor is formed and a peripheral region in which a peripheral circuit is formed, the device comprising:
a semiconductor substrate of a first conductivity type;
a first well of a second conductivity type selectively formed in a surface portion of the semiconductor substrate;
a second well of the first conductivity type selectively formed in a surface portion of the first well;
a first element isolating insulation film formed in a surface portion of the second well, the first element isolating insulation film isolating the memory cell region from the peripheral region;
a cell transistor provided in the second well in the memory cell region, the cell transistor comprising a gate electrode provided on the second well with a gate insulating film interposed therebetween and source and drain layers formed in the second well to sandwich a portion of the second well under the gate electrode;
a first contact layer of the second conductivity type formed in a surface portion of the first well in the peripheral region, the first contact layer providing the first well with a potential; and
a second contact layer of the first conductivity type formed in a surface portion of the second well in the peripheral region, the second contact layer providing the second well with a potential.

2. A device according to claim 1, wherein the first element isolating insulation film has a substantially U-shaped trench formed in an upper portion thereof.

3. A device according to claim 1, further comprising a peripheral transistor for the peripheral circuit, provided outside the first well in the peripheral region, the peripheral transistor comprising a gate electrode provided on the semiconductor substrate with a gate insulating film interposed therebetween and source and drain layers formed in the semiconductor substrate to sandwich a portion of the semiconductor substrate under the gate electrode.

4. A device according to claim 3, wherein:
the gate electrode in the cell transistor comprises a first conductive film derived from a first conductive material and a second conductive film derived from a second conductive material provided above the first conductive film; and
the gate electrode in the peripheral region comprises a third conductive film derived from the second conductive material.

5. A device according to claim 1, wherein the second contact layer has an impurity concentration at most eight times that of the source and drain regions of the cell transistor.

6. A device according to claim 1, further comprising a second element isolating insulation film respectively formed at edge portions of the first and second wells, the second element isolating insulation film having a cross-section smaller than that of the first element isolating insulation film.

7. A device according to claim 1, comprising a plurality of structures each having the first and second wells, the first element isolating insulation film, the cell transistor and the first and second contact layers, and
the first and second wells, the first element isolating insulation films, the cell transistors and the first and second contact layers being formed in the semiconductor substrate.

8. A semiconductor memory device having a memory cell region in which a cell transistor is formed and a peripheral region in which a peripheral circuit is formed, the device comprising:
a semiconductor substrate of a first conductivity type;
a first well of a second conductivity type selectively formed in a surface portion of the semiconductor substrate;
a second well of the first conductivity type selectively formed in a surface portion of the first well;
a first element isolating insulation film formed in a plane of the second well so as to surround the memory cell region, the first element isolating insulation film isolating the memory cell region from the peripheral region;
a cell transistor provided in the memory cell region, the cell transistor comprising a gate electrode provided on the second well with a gate insulating film interposed therebetween and source and drain layers formed in the second well to sandwich a portion of the second well under the gate electrode;
a first contact layer of the second conductivity type formed in a surface portion of the first well in the peripheral region, the first contact layer providing the first well with a potential; and
a second contact layer of the first conductivity type formed in a surface portion of the second well in the peripheral region, the second contact layer providing the second well with a potential.

9. A device according to claim 8, wherein the first element isolating insulation film has a substantially U-shaped trench formed in an upper portion thereof.

10. A device according to claim 8, further comprising a peripheral transistor for the peripheral circuit, provided outside the first well in the peripheral region, the peripheral transistor comprising a gate electrode provided on the semiconductor substrate with a gate insulating film interposed therebetween and source and drain layers formed in the semiconductor substrate to sandwich a portion of the semiconductor substrate under the gate electrode.

11. A device according to claim 10, wherein:
the gate electrode of the cell transistor comprises a first conductive film derived from a first conductive material and a second conductive film derived from a second conductive material provided above the first conductive film; and
the gate electrode in the peripheral region comprises a third conductive film derived from the second conductive material.

12. A device according to claim 8, wherein the second contact layer has an impurity concentration at most eight times that of the source and drain regions of the cell transistor.

13. A device according to claim 8, further comprising a second element isolating insulation film respectively formed at edge portions of the first and second wells, the second element isolating insulation film having a cross-section smaller than that of the first element isolating insulation film.

14. A device according to claim 8, comprising a plurality of structures each having the first and second wells, the first element isolating insulation film, the cell transistor and the first and second contact layers, and
the first and second wells, the first element isolating insulation films, the cell transistors and the first and second contact layers being formed in the semiconductor substrate.

15. A method for manufacturing a semiconductor memory device having a memory cell region in which a cell transistor is formed and a peripheral region in which a peripheral circuit is formed, the method comprising:
forming a well in a surface portion of a semiconductor substrate;
forming an element isolating insulation film in a plane of the well so as to surround the memory cell region, the element isolating insulation film isolating the memory cell region from the peripheral region;
forming a first gate insulation film, a first conductive film and a first insulation film, successively, on the well in the memory cell region;
forming a second gate insulation film outside the well in the peripheral region;
forming a second conductive film over the first insulation film and the second gate insulation film;
forming a mask layer on the second conductive film, the mask layer having a gate pattern of the cell transistor and covering the peripheral region;
forming a gate structure of the cell transistor by etching the second conductive film, the first insulation film and the first conductive film in the memory cell region, using the mask layer as a mask;
forming source and drain regions of the cell transistor by implanting an impurity into the surface portion of the semiconductor substrate, using the mask layer as a mask; and
forming a gate structure and source and drain regions of the peripheral transistor.

16. A method according to claim 15, wherein the successively forming a first gate insulation film, a first conductive film and a first insulation film on the well in the memory cell region comprises etching the first conductive film from above the element isolating insulation film until a substantially U-shaped trench is formed in an upper portion of the element isolating insulation film, after the first conductive film is formed in the memory cell region and the peripheral region.

17. A method for manufacturing a semiconductor memory device having a memory cell region in which a cell transistor is formed and a peripheral region in which a peripheral circuit is formed, the method comprising:
forming a first well of a second conductivity type in a surface portion of a semiconductor substrate of a first conductivity type;
forming a second well of the first conductivity type in a surface portion of the first well;
forming an element isolating insulation film in a plane of the second well so as to surround the memory cell region, the element isolating insulation film isolating the memory cell region from the peripheral region;
forming a first gate insulation film, a first conductive film and a first insulation film, successively, on the second well in the memory cell region;
forming a second gate insulation film outside the first well in the peripheral region;
forming a second conductive film over the first insulation film and the second gate insulation film;
forming a mask layer on the second conductive film, the mask layer having a gate pattern of the cell transistor and covering at least the peripheral region;
forming a gate structure of the cell transistor by etching the second conductive film, the first insulation film and the first conductive film in the memory cell region, using the mask layer as a mask;
forming source and drain regions of the cell transistor by implanting an impurity into the surface portion of the semiconductor substrate, using the mask layer as a mask;
forming a gate structure and source and drain regions of the peripheral transistor;
forming a first contact layer of the second conductivity type by implanting an impurity of the second conductivity type into a surface portion of the first well in the peripheral region, the first contact layer providing the first well with a potential; and
forming a second contact layer of the first conductivity type by implanting an impurity of the first conductivity type into a surface portion of the second well in the peripheral region, the second contact layer providing the second well with a potential.

18. A method according to claim 17, wherein the successively forming a first gate insulation film, a first conductive film and a first insulation film on the first well in the memory cell region comprises etching the first conductive film from above the element isolating insulation film until a substantially U-shaped trench is formed in an upper portion of the element isolating insulation film, after the first conductive film is formed in the memory cell region and the peripheral region.

19. A method according to claim 17, wherein the second contact layer has an impurity concentration at most eight times that of the source and drain regions of the cell transistor.
